(19) United States
(12) Patent Application Publication
(10) Pub. No.: US 2025/0040361 A1
(43) Pub. Date: Jan. 30, 2025

(54) DISPLAY PANEL AND METHOD FOR MANUFACTURING THE SAME

(71) Applicant: Samsung Display Co., LTD., Yongin-si (KR)

(72) Inventors: SOO BEOM JO, Yongin-si (KR); GUANGHAI JIN, Yongin-si (KR)

(21) Appl. No.: 18/643,690

(22) Filed: Apr. 23, 2024

(30) Foreign Application Priority Data
Jul. 28, 2023 (KR) 10-2023-0098769

(51) Int. Cl. H10K 59/124; H10K 59/12

(52) U.S. Cl. CPC H10K 59/124; H10K 59/1201

(57) ABSTRACT

A display panel includes a base layer; a transistor which includes a semiconductor pattern, a gate which overlaps the semiconductor pattern, a source and a drain connected to the semiconductor pattern; a light-emitting element; a capacitor which includes a first electrode disposed in a same layer as the semiconductor pattern and a second electrode disposed on the first electrode; an inter-insulating layer disposed between the semiconductor pattern and the gate; and an intermediate insulating layer which is disposed between the gate and the source and the drain and includes a groove which exposes the second electrode. A side surface, of the intermediate insulating layer, which defines the groove includes a first side surface which contacts the second electrode, an upper surface which overlaps a portion of the first electrode, and a second side surface spaced apart from the first side surface.

This application claims priority to Korean Patent Application No. 10-2023-0098769, filed on Jul. 28, 2023, and all the benefits accruing therefrom under 35 U.S.C. § 119, the content of which in its entirety is herein incorporated by reference.

### BACKGROUND

### 1. Field

The disclosure herein relates to a display panel and a method for manufacturing the same, and more particularly, to a display panel manufactured through a simplified process and a method for manufacturing the same.

### 2. Description of the Related Art

A display panel includes a plurality of pixels and a driving circuit (e.g., a scan driving circuit and a data driving circuit) that controls the plurality of pixels. Each of the plurality of pixels includes a display element and a pixel driving circuit that controls the display element. The pixel driving circuit may include a plurality of transistors organically connected to each other.

The scan driving circuit and/or the data driving circuit may be formed through the same process as that of the plurality of pixels. The scan driving circuit and/or the data driving circuit may include a plurality of transistors organically connected to each other.

### SUMMARY

The disclosure provides a display panel manufactured through a simplified process and a method for manufacturing the same.

An embodiment of the inventive concept provides a display panel including: a base layer; a transistor disposed on the base layer and including a semiconductor pattern, a gate overlapping the semiconductor pattern, and a source and a drain connected to the semiconductor pattern; a light-emitting element connected to the transistor; a capacitor including a first electrode disposed in a same layer as the semiconductor pattern and a second electrode disposed on the first electrode; an inter-insulating layer disposed between the semiconductor pattern and the gate; and an intermediate insulating layer disposed between the gate and the source and gate and the drain and including a groove which exposes the second electrode. A side surface of the intermediate insulating layer which defines the groove includes a first side surface in contact with the second electrode, an upper surface overlapping a portion of the first electrode, and a second side surface spaced apart from the first side surface.

In an embodiment, the inter-insulating layer and the intermediate insulating layer may be disposed on the portion of the first electrode and the portion of the first electrode may not overlap the second electrode.

In an embodiment, the source and the drain may contact the semiconductor pattern through contact holes which penetrate the inter-insulating layer and the intermediate insulating layer.

In an embodiment, the gate and the second electrode may be disposed on the inter-insulating layer, and a first thickness of the second electrode may be smaller than a second thickness of the gate.

In an embodiment, a difference between the second thickness and the first thickness may range from about 400 angstroms (Å) to about 700 Å.

In an embodiment, the display panel may further include a lower insulating layer which is disposed on the base layer and on which the first electrode and the semiconductor pattern are disposed, and an upper insulating layer which is disposed on the intermediate insulating layer and covers the source and the drain.

In an embodiment, the upper insulating layer may be disposed in the groove and contact the second electrode.

In an embodiment, the display panel may further include an upper insulating layer, and the light-emitting element may include an anode connected to the transistor through a contact hole which penetrates the upper insulating layer, a cathode disposed on the anode, and a light-emitting layer disposed between the anode and the cathode.

In an embodiment, the first electrode may include polysilicon, and the second electrode may include molybdenum.

In an embodiment, the polysilicon may be impregnated with boron.

In an embodiment, the semiconductor pattern may include polysilicon.

In an embodiment, the display panel may further include a thin-film encapsulation layer to cover the light-emitting element.

In an embodiment of the inventive concept, a method for manufacturing a display panel, the method includes: forming a first electrode and a semiconductor pattern on a base layer; forming an inter-insulating layer which covers the first electrode and the semiconductor pattern; forming, on the inter-insulating layer, a second electrode overlapping the first electrode, and a gate overlapping the semiconductor pattern; doping the first electrode which does not overlap the second electrode, and the semiconductor pattern which does not overlap the gate; forming an intermediate insulating layer which covers the second electrode and the gate, and a photoresist layer on the intermediate insulating layer; forming a stepped region in the photoresist layer which overlaps an end of the second electrode through a half-tone mask in which a plurality of slits is defined, and patterning the photoresist layer so that the intermediate insulating layer overlapping a portion of the second electrode is exposed; patterning the intermediate insulating layer so that the portion of the second electrode is exposed; removing the stepped region of the photoresist layer; and removing the intermediate insulating layer exposed by the photoresist layer through the removing the stepped region, where the stepped region overlaps a portion of the first electrode which does not overlap the second electrode, and the inter-insulating layer remains on the portion of the first electrode.

In an embodiment, the patterning the photoresist layer may include removing a portion of a region, of the inter-insulating layer, which is spaced apart from the gate and overlaps the semiconductor pattern, and removing the inter-insulating layer exposed by the photoresist layer may include removing the portion of the inter-insulating layer so that the semiconductor pattern is exposed.

In an embodiment, the method may further include forming a source and a drain on the inter-insulating layer, and the source and the drain being in contact with the semiconductor pattern exposed by the inter-insulating layer.

In an embodiment, the method may further include forming an intermediate insulating layer on the inter-insulating layer so that the source and the drain are covered, where the intermediate insulating layer may contact the portion of the second electrode exposed by the inter-insulating layer.

In an embodiment, the method may further include: defining a contact hole in the intermediate insulating layer so that a portion of the source is exposed; and forming an anode connected to the source through the contact hole.

In an embodiment, the first electrode and the semiconductor pattern may include polysilicon.

In an embodiment, the method may further include, after the removing the inter-insulating layer exposed by the photoresist layer, doping a portion, of the first electrode, which overlaps the second electrode.

In an embodiment, after patterning the inter-insulating layer, a thickness of the second electrode may become smaller than a thickness of the gate.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an embodiment of a display panel according to the inventive concept;

FIG. 1B is a perspective view of an embodiment of a curved display panel according to the inventive concept;

FIG. 2 is a cross-sectional view of an embodiment of a display panel according to the inventive concept;

FIG. 3 is a plan view of an embodiment of a display panel according to the inventive concept;

FIG. 4 is an equivalent circuit diagram of an embodiment of a pixel according to the inventive concept;

FIG. 5 is a cross-sectional view of an embodiment of a display panel according to the inventive concept;

FIG. 6 is a cross-sectional view of an embodiment of a display panel according to the inventive concept; and

FIGS. 7A to 7M are cross-sectional views illustrating an embodiment of a method for manufacturing a display panel according to the inventive concept.

### DETAILED DESCRIPTION

In this specification, when an element (or a region, a layer, a portion etc.) is referred to as being “on”, “connected to” or “coupled to” another element, it may be directly on, connected or coupled to the other element or intervening elements may be disposed therebetween.

Like numerals or symbols refer to like elements throughout. In addition, in the drawings, thicknesses, ratios, and dimensions of elements are exaggerated for effective description of the technical contents. The term “and/or” includes all of one or more combinations that the associated elements may define.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

In addition, terms such as “below”, “lower”, “above”, “upper” are used to describe the relationships of the elements illustrated in the drawings. The terms are relative concepts and are described on the basis of the directions indicated in the drawings.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by a person skill in the art. In addition, terms such as those defined in commonly used dictionaries should be interpreted as having a meaning that is consistent with their meaning in the context of the relevant art and will not be interpreted in an overly idealized or overly formal sense unless expressly so defined herein.

Hereinafter, embodiments of the inventive concept will be described with reference to the drawings.

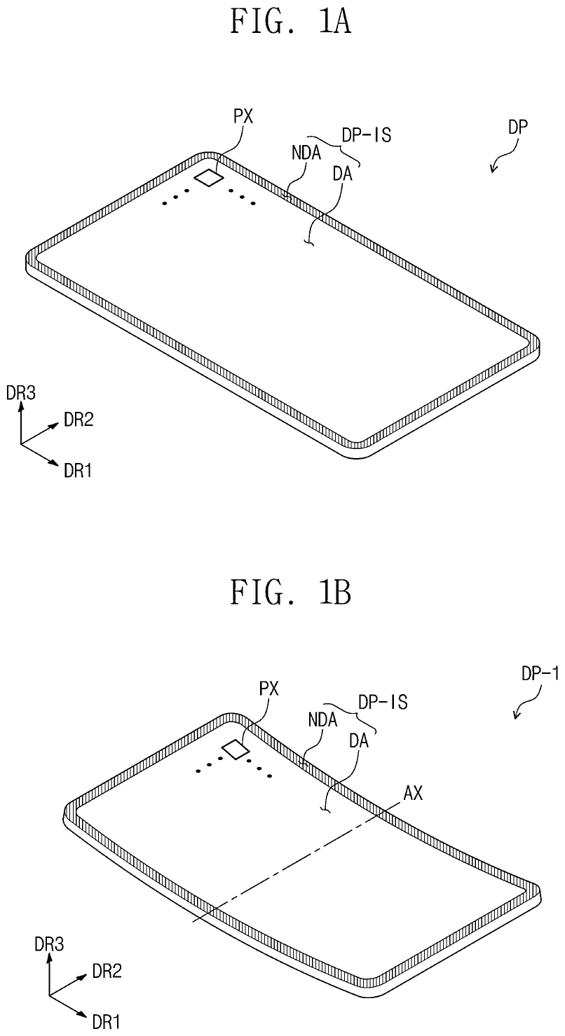

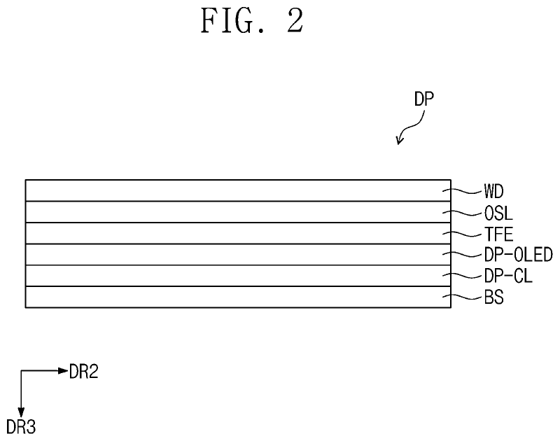

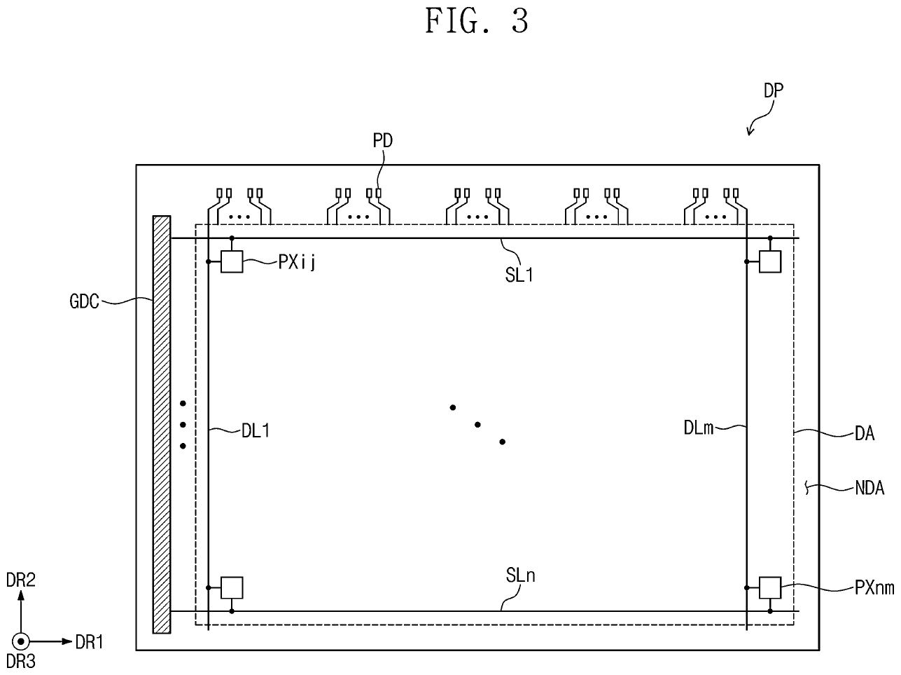

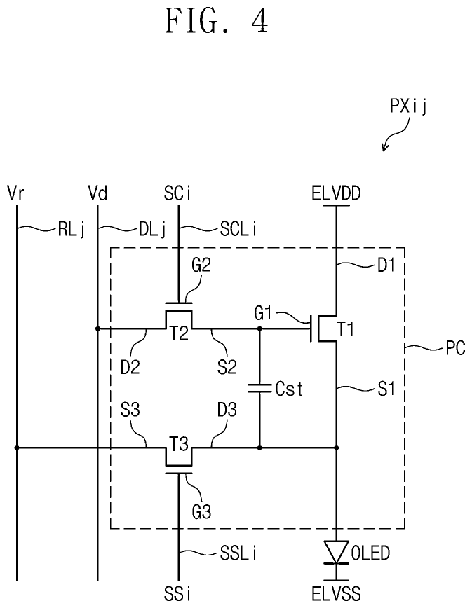

FIG. 1A is a perspective view of an embodiment of a display panel according to the inventive concept. FIG. 1B is a perspective view of an embodiment of a curved display panel according to the inventive concept. FIG. 2 is a cross-sectional view of an embodiment of a display panel according to the inventive concept. FIG. 3 is a plan view of an embodiment of a display panel according to the inventive concept. FIG. 4 is an equivalent circuit diagram of an embodiment of a pixel according to the inventive concept.

Display panels DP and DP−1 illustrated in FIG. 1A and FIG. 1B are light-emitting display panels, and may be any one of liquid crystal display panels, electrophoretic display panels, microelectromechanical system display panels, electrowetting display panels, organic light-emitting display panels, inorganic light-emitting display panels, or quantum-dot display panels, but an embodiment of the inventive concept is not particularly limited thereto.

Referring to FIG. 1A, the display panel DP may display an image through a display surface DP-IS. A top surface of a member disposed on the uppermost side of the display panel DP may be defined as the display surface DP-IS. According to the inventive concept, a top surface of a window panel WD illustrated in FIG. 2 may be defined as the display surface DP-IS of the display panel DP.

The display surface DP-IS is parallel to a plane defined by a first direction DR1 and a second direction DR2. A normal direction of the display surface DP-IS, i.e., a thickness direction of the display panel DP, is indicated by a third direction DR3. A front surface (or an upper surface) and a rear surface (or a lower surface) of each layer or unit to be described below are distinguished based on the third direction DR3.

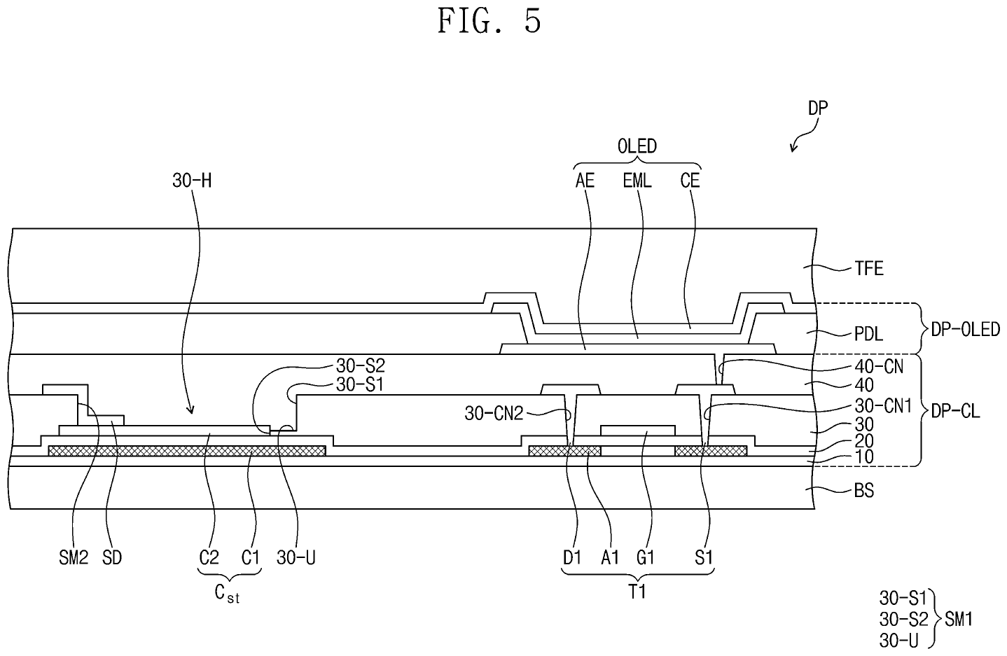

The display panel DP may include a display region DA and a non-display region NDA. A light-emitting layer EML (refer to FIG. 5) of a pixel PX is disposed in the display region DA and is not disposed in the non-display region NDA. The non-display region NDA is defined along an edge of the display surface DP-IS. The non-display region NDA may surround the display region DA. In an embodiment of the inventive concept, the non-display region NDA may be omitted or disposed on only one side of the display region DA.

Referring to FIG. 1B, the display panel DP−1 in an embodiment may be curved along the first direction DR1 with respect to a virtual axis AX extending in the second direction DR2. However, the inventive concept is not limited thereto, and an axis may extend in the first direction DR1, or the display panel DP−1 may be curved with respect to a plurality of axes extending in different directions.

In addition, the display panel DP may be a rollable display panel, a foldable display panel, or a slidable display panel. The display panel DP may have a flexible property and be capable of folding or rolling while being installed on a display device. Accordingly, the display panel DP may include a curved display surface DP-IS or a stereoscopic display surface DP-IS. The stereoscopic display surface DP-IS may include a plurality of display regions which indicate different directions.

FIG. 1A and FIG. 1B illustrate a pixel PX disposed in the display region DA. The pixel PX may include one or more subpixels that provide different light. In an embodiment, the pixel PX may be a region in which subpixels providing green, red, and blue light are provided. The subpixels included in the pixel PX may be arranged in a stripe or Pen-Tile™ shape, for example.

However, the inventive concept is not limited thereto, and the subpixels generating different light may be arranged in a triangular shape. In an embodiment, a light-emitting region of a subpixel providing green light and a light-emitting region of a subpixel providing red light may be spaced apart from each other in the first direction DR1, and a light-emitting region of a subpixel providing blue light may be spaced apart from the light-emitting region of the subpixel providing green light and the light-emitting region of the subpixel providing red light in a diagonal direction with respect to each of the first direction DR1 and the second direction DR2, for example. In this case, among the subpixels, the subpixel providing red light may have the largest light-emitting region, and the subpixel providing blue light may have the smallest light-emitting region.

In addition, the shape of the light-emitting region of the subpixel providing green light and the shape of the light-emitting region of the subpixel providing red light may be symmetrical to each other. In this case, the light-emitting regions may have similar shapes to each other while having different areas from each other. The light-emitting region of the subpixel providing blue light may be symmetrical with respect to a virtual line crossing the center of the light-emitting region. However, the inventive concept is not limited thereto, and an arrangement of subpixels providing different light and area sizes of light-emitting regions of the subpixels are not limited to a particular embodiment.

Referring to FIG. 2, the display panel DP according to the inventive concept includes a base layer BS, a circuit element layer DP-CL disposed on the base layer BS, a display element layer DP-OLED, a thin-film encapsulation layer TFE, a light control layer OSL, and a window panel WD. The display panel DP may further include functional layers such as an anti-reflective layer or a refractive index adjusting layer. The circuit element layer DP-CL may include at least a plurality of insulating layers and a circuit element. The insulating layers to be described below may include an organic layer and/or an inorganic layer.

The base layer BS may include a synthetic resin layer. The synthetic resin layer may include a thermosetting resin. More particularly, the synthetic resin layer may be a polyimide-based resin layer, but the material thereof is not particularly limited thereto. The synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, an organic/inorganic composite material substrate, or the like.

In the circuit element layer DP-CL, an insulating layer, a semiconductor layer, and a conductive layer are formed through processes such as coating or deposition. Then, the insulating layer, the semiconductor layer, and the conductive layer may be selectively patterned through photolithography and etching processes. Through such processes, a semiconductor pattern, a conductive pattern, a signal line, etc., are formed. Patterns disposed in the same layer are formed through the same process. According to the inventive concept, one or more insulating layers included in the circuit element layer DP-CL may be formed with a half tone mask in which a plurality of slits is defined. Description thereof will be made later.

The circuit element layer DP-CL includes a signal line or a driving circuit for driving the pixel PX. The display element layer DP-OLED may include a pixel defining film PDL (refer to FIG. 5) and a light-emitting element OLED (refer to FIG. 5) included in the pixel PX.

The thin-film encapsulation layer TFE may be disposed on the display element layer DP-OLED to protect the light-emitting element OLED. The thin-film encapsulation layer TFE may include inorganic layers and an organic layer disposed between the inorganic layers. The inorganic layers may protect the light-emitting element OLED from moisture and oxygen, and the organic layer may protect the light-emitting element OLED from foreign substances such as dust particles.

The light control layer OSL may include color control layers capable of converting an optical property of source light generated from the light-emitting element OLED. The color control layers may include quantum-dots, and the light control layer OSL may include color filters which selectively transmit light transmitted through the color control layers.

In an embodiment, the light control layer OSL may be spaced apart from the thin-film encapsulation layer TFE with a predetermined space therebetween. In this case, the light control layer OSL may be formed on the window panel WD which serves as a base layer. The base layer BS to the thin-film encapsulation layer TFE may be defined as a lower panel, and the light control layer OSL and the window panel WD may be defined as an upper panel. The lower panel and the upper panel may be bonded together with a resin disposed in the non-display region NDA.

However, the inventive concept is not limited thereto, and the light control layer OSL may be directly formed on the thin-film encapsulation layer TFE through a continuous process.

The window panel WD may be disposed in an upper portion of the display panel DP and transmit an image provided from the display panel DP to the outside. The window panel WD includes the display region DA and the non-display region NDA. The non-display region NDA may define a boundary of the display region DA and be defined by a bezel pattern which is disposed under the window panel WD and absorbs light.

The window panel WD may include a base layer and functional layers disposed on the base layer. The functional layers may include a protective layer, a fingerprint-resistant layer, etc. The base layer of the window panel WD may include glass, sapphire, plastic, or the like.

FIG. 3 illustrates a planar arrangement relationship of signal lines SL1 to SLn and DL1 to DLm, and pixels PX11 to PXnm, which are included in the display panel DP. Here, n and m are natural numbers. The signal lines SL1 to SLn and DL1 to DLm may include a plurality of scan lines SL1 to SLn, and a plurality of data lines DL1 to DLm.

Each of the pixels PX11 to PXnm is connected to a corresponding scan line among the plurality of scan lines SL1 to SLn, and a corresponding data line among the plurality of data lines DL1 to DLm. Each of the pixels PX11 to PXnm may include a pixel driving circuit and a display element. More types of signal lines may be provided to the display panel DP according to configurations of the pixel driving circuits of the pixels PX11 to PXnm. In an embodiment the data lines DL1 to DLm may be connected to pads PD, respectively, disposed in the non-display region NDA.

A gate driving circuit GDC may be disposed in the non-display region NDA. The gate driving circuit GDC may be integrated into the display panel DP through an oxide silicon gate (“OSG”) driver circuit process or an amorphous silicon gate (“ASG”) driver circuit process.

FIG. 4 illustrates a circuit diagram of one pixel PXij of the pixels PX11 to PXnm. Here, i and j may be natural numbers equal to or less than n and m, respectively.

Referring to FIG. 4, the pixel PXij may include a pixel circuit PC and a light-emitting element OLED. The pixel circuit PC may include a plurality of transistors T1 to T3 and a capacitor Cst.

The plurality of transistors T1 to T3 may be formed through a low temperature polycrystalline silicon (“LTPS”) process or a low temperature polycrystalline oxide (“LTPO”) process. First to third transistors T1 to T3 may each include any one among a silicon semiconductor and an oxide semiconductor. In this case, the oxide semiconductor may include a crystalline or amorphous oxide semiconductor, and the silicon semiconductor may include amorphous silicon, polycrystalline silicon, etc., and the inventive concept is not limited thereto.

Hereinafter, the first to third transistors T1 to T3 are described as N-type transistors, but the inventive concept is not limited thereto, and each of the first to third transistors T1 to T3 may be a P-type transistor or a N-type transistor according to signals applied thereto. In this case, a source and a drain of the P-type transistor may correspond to a drain and a source of the N-type transistor, respectively.

In an embodiment, the capacitor Cst included in the pixel circuit PC may include two electrodes spaced apart from each other. In this case, an electrode disposed on a lower side than the other may be doped with a P-type dopant. Description thereof will be made later.

FIG. 4 illustrates a pixel PXij which is connected to an i-th scan line SCLi, an i-th sensing line SSLi, a j-th data line DLj, and a j-th reference line RLj.

The pixel circuit PC may include the first transistor T1 (a driving transistor), the second transistor T2 (a switching transistor), the third transistor T3 (a sensing transistor), and the capacitor Cst. However, the pixel circuit PC may further include an additional transistor and an additional capacitor, and the inventive concept is not limited thereto.

The first to third transistors T1 to T3 may respectively include sources S1, S2, and S3, drains D1, D2, and D3, and gates G1, G2, and G3.

The light-emitting element OLED may be an organic light-emitting element or an inorganic light-emitting element including an anode (a first electrode) and a cathode (a second electrode). The anode of the light-emitting element OLED may receive a first voltage ELVDD through the first transistor T1, and the cathode of the light-emitting element OLED may receive a second voltage ELVSS. The light-emitting element OLED may emit light upon receiving the first voltage ELVDD and the second voltage ELVSS.

The first transistor T1 may include the drain D1 which receives the first voltage ELVDD, the source S1 which is connected to the anode of the light-emitting element OLED, and the gate G1 which is connected to the capacitor Cst. The first transistor T1 may control a drive current flowing through the light-emitting element OLED from the first voltage ELVDD in response to a voltage value stored in the capacitor Cst.

The second transistor T2 may include the drain D2 which is connected to the j-th data line DLj, the source S2 which is connected to the capacitor Cst, and the gate G2 which receives an i-th write scan signal SCi. The second transistor T2 provides a data voltage Vd to the first transistor T1 in response to the i-th write scan signal SCi.

The third transistor T3 may include the source S3 which is connected to the j-th reference line RLj, the drain D3 which is connected to the anode of the light-emitting element OLED, and the gate G3 which receives an i-th sampling scan signal SSi. The j-th reference line RLj may receive a reference voltage Vr.

The capacitor Cst may store voltage differences of various values according to input signals. In an embodiment, the capacitor Cst may store a voltage equivalent to a difference between a voltage transmitted from the second transistor T2 and the first voltage ELVDD, for example.

In the inventive concept, an equivalent circuit of the pixel PXij is not limited to the equivalent circuit illustrated in FIG. 4. In other embodiments of the inventive concept, the pixel PXij may be implemented in various forms to cause the light-emitting element OLED to emit light.

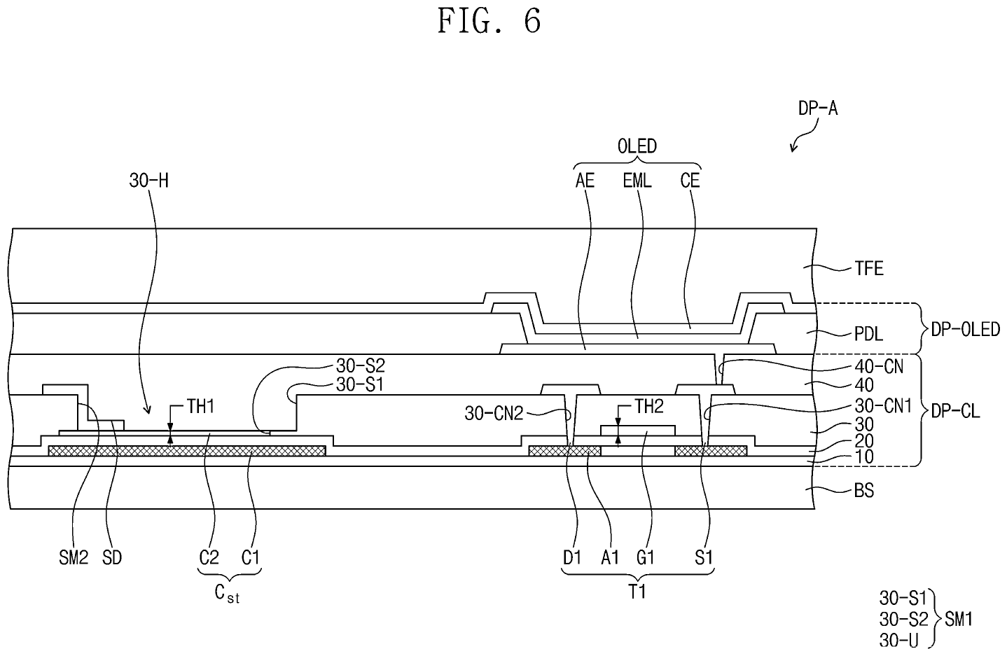

FIG. 5 is a cross-sectional view of an embodiment of a display panel according to the inventive concept. FIG. 6 is a cross-sectional view of an embodiment of a display panel according to the inventive concept. FIG. 5 illustrates only some components of the display panel DP illustrated in FIG. 2, that is, the base layer BS to the thin-film encapsulation layer TFE.

Referring to FIG. 5, a display panel DP in an embodiment may include a base layer BS, a circuit element layer DP-CL disposed on the base layer BS, a display element layer DP-OLED disposed on the circuit element layer DP-CL, and a thin-film encapsulation layer TFE disposed on the display element layer DP-OLED.

A first insulating layer 10 (or a lower insulating layer) may be disposed on the base layer BS. In an embodiment, the first insulating layer 10 may be a buffer layer and include an inorganic layer having a single- or multi-layered structure.

A first electrode C1 of a capacitor Cst and a semiconductor pattern A1 may be disposed on the first insulating layer 10. The first electrode C1 and the semiconductor pattern A1 may be formed through the same process and may include the same material as each other. In an embodiment, the first electrode C1 and the semiconductor pattern A1 may include polysilicon, for example. A P-type doping process may be performed on the first electrode C1 and the semiconductor pattern A1. After the doping process, the first electrode C1 and the semiconductor pattern A1 may be impregnated with boron. Description thereof will be made later.

A second insulating layer 20 (or an inter-insulating layer) may be disposed on the first insulating layer 10 and cover the first electrode C1 and the semiconductor pattern A1. The second insulating layer 20 may include an inorganic layer having a single- or multi-layered structure.

A gate G1 may be disposed on the second insulating layer 20. The gate G1 may overlap the semiconductor pattern A1. In an embodiment, the gate G1 may function as a mask in the doping process of the semiconductor pattern A1. Accordingly, a region of the semiconductor pattern A1 overlapping the gate G1 may be defined as a channel region.

A second electrode C2 of the capacitor Cst may be disposed on the second insulating layer 20. The second electrode C2 may overlap the first electrode C1. In an embodiment, the second electrode C2 may not overlap a portion of the first electrode C1. The second electrode C2 and the gate G1 may be formed through the same process and may include the same material as each other.

A third insulating layer 30 (or an intermediate layer) may be disposed on the second insulating layer 20 and cover the gate G1. In an embodiment, the third insulating layer 30 may include an organic layer. Contact holes 30-CN1 and 30-CN2 may be defined in the third insulating layer 30 by penetration of the third insulating layer 30. Each of the contact holes 30-CN1 and 30-CN2 may expose a doped region of the semiconductor pattern A1. A source S1 may be disposed in a first contact hole 30-CN1 and connected to one region of the semiconductor pattern A1. A drain D1 may be disposed in a second contact hole 30-CN2 and connected to another region of the semiconductor pattern A1.

According to the inventive concept, a groove 30-H which exposes at least a portion of the second electrode C2 may be defined in the third insulating layer 30. The groove 30-H may be defined by penetration of the third insulating layer 30. The groove 30-H may be defined by one side surface SM1 and another side surface SM2 of the third insulating layer 30 exposed by the penetration. The one side surface SM1 and the another side surface SM2 may face each other in a cross-section.

In an embodiment, the one side surface SM1 may include a first side surface 30-S1, a second side surface 30-S2, and an upper surface 30-U.

The first side surface 30-S1 may contact one side of the second electrode C2. The upper surface 30-U may extend from the first side surface 30-S1 and may be connected to the second side surface 30-S2. The upper surface 30-U may overlap a portion, of the first electrode C1, exposed from the second electrode C2. Another side opposite to the one side of the second electrode C2 may be disposed in the another side surface SM2.

According to the inventive concept, a width from the first side surface 30-S1 to the another side surface SM2 may be smaller than a width from the second side surface 30-S2 to the another side surface SM2. Accordingly, the second insulating layer 20 and the third insulating layer 30 may be disposed on the portion, of the first electrode C1, exposed from the second electrode C2.

In an embodiment, the display panel DP may further include a conductive pattern SD which is disposed in the groove 30-H adjacent to the another side surface SM2 and is in contacts the another side surface SM2, an upper surface of the third insulating layer 30, and the second electrode C2. The conductive pattern SD and the source S1 and the drain D1 may be formed through the same process and may include the same material as each other. In an embodiment, the conductive pattern SD may be branched off from a portion of either of the source S1 or the drain D1.

A fourth insulating layer 40 (or an upper insulating layer) may be disposed on the third insulating layer 30 and cover the gate G1. In an embodiment, the fourth insulating layer 40 may include an organic layer. A contact hole 40-CN may be defined in the fourth insulating layer 40 by penetration of the fourth insulating layer 40.

A first electrode AE of a light-emitting element OLED is disposed on the fourth insulating layer 40. The first electrode AE may be an anode. The first electrode AE may be connected to the source S1 through the contact hole 40-CN. A pixel defining film PDL is disposed on the fourth insulating layer 40. An opening which exposes at least a portion of the first electrode AE may be defined in the pixel defining film PDL. The opening of the pixel defining film PDL may be defined as a light-emitting region which provides light. A light-emitting layer EML is disposed on the first electrode AE. The light-emitting layer EML in an embodiment may be disposed only in a region corresponding to the opening OP. The light-emitting layer EML may be formed separately in each of a plurality of pixels PX.

In the illustrated embodiment, a patterned light-emitting layer EML is illustrated, but the light-emitting layer EML may be disposed in common in the plurality of pixels PX. The light-emitting layer EML disposed in common may generate white light or blue light. In addition, the light-emitting layer EML may have a multi-layered structure. A second electrode CE is disposed on the light-emitting layer EML. An electron control layer and the second electrode CE may be disposed in common in the plurality of pixels.

In an embodiment, the display panel DP may further include a hole control layer disposed between the first electrode AE and the light-emitting layer EML, and an electron control layer disposed between the light-emitting layer EML and the second electrode CE. The hole control layer may include a hole transport layer and a hole injection layer, and the electron control layer may include an electron transport layer and an electron injection layer. The hole control layer and the electron control layer may be common layers disposed in common in the plurality of pixels PX.

The thin-film encapsulation layer TFE includes at least one of an inorganic layer and/or an organic layer. The inorganic layer in an embodiment may be provided in plural and disposed on and below the organic layer. In addition, any one among the inorganic layer and the organic layer may include two or more layers, and the inventive concept is not limited thereto.

According to the inventive concept, a process for defining the contact holes 30-CN1 and 30-CN2 for connecting the source S1 and the drain D1 to the semiconductor pattern A1, and a process for doping the first electrode C1 of the capacitor Cst may be performed in the same mask process. Accordingly, manufacturing costs of the display panel DP may be reduced, and a manufacturing process of the display panel DP may be simplified. Description thereof will be made later.

Referring to FIG. 6, a display panel DP-A in an embodiment may include a base layer BS, a circuit element layer DP-CL disposed on the base layer, a display element layer DP-OLED disposed on the circuit element layer DP-CL, and a thin-film encapsulation layer TFE disposed on the display element layer DP-OLED. A difference between the display panel DP described with reference to FIG. 5 and the display panel DP-A will be mainly described.

The display panel DP-A may include a capacitor Cst which includes a first electrode C1 and a second electrode C2. The first electrode C1 may be spaced apart from the second electrode C2 with a second insulating layer 20 therebetween. The first electrode C1 and a semiconductor pattern A1 may be formed through the same process and may include the same material as each other. The second electrode C2 and a gate G1 may be formed through the same process and may include the same material as each other.

The second electrode C2 in an embodiment may have a first thickness TH1, and the gate G1 may have a second thickness TH2. The first thickness TH1 may be smaller than the second thickness TH2. A difference between the second thickness TH2 and the first thickness TH1 may range from about 400 angstroms (Å) to about 700 Å. The reason may be that the second electrode C2 has a smaller thickness than the gate G1 as an upper portion of the second electrode C2 is partially etched during an etching process for defining a groove 30-H in a third insulating layer 30.

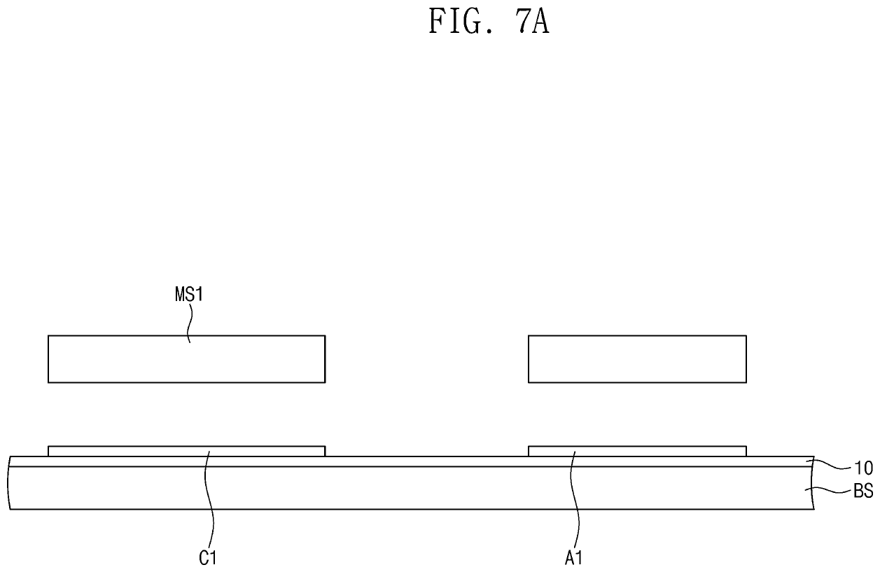

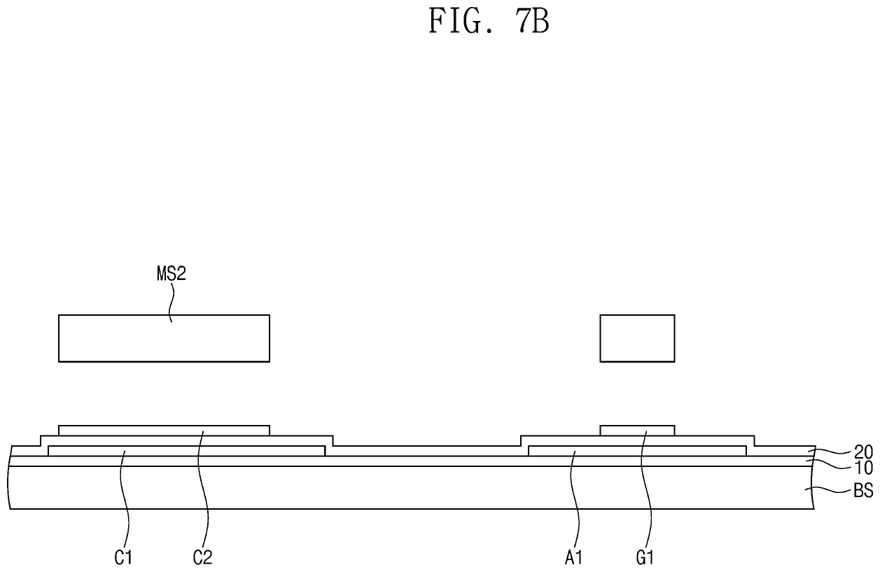

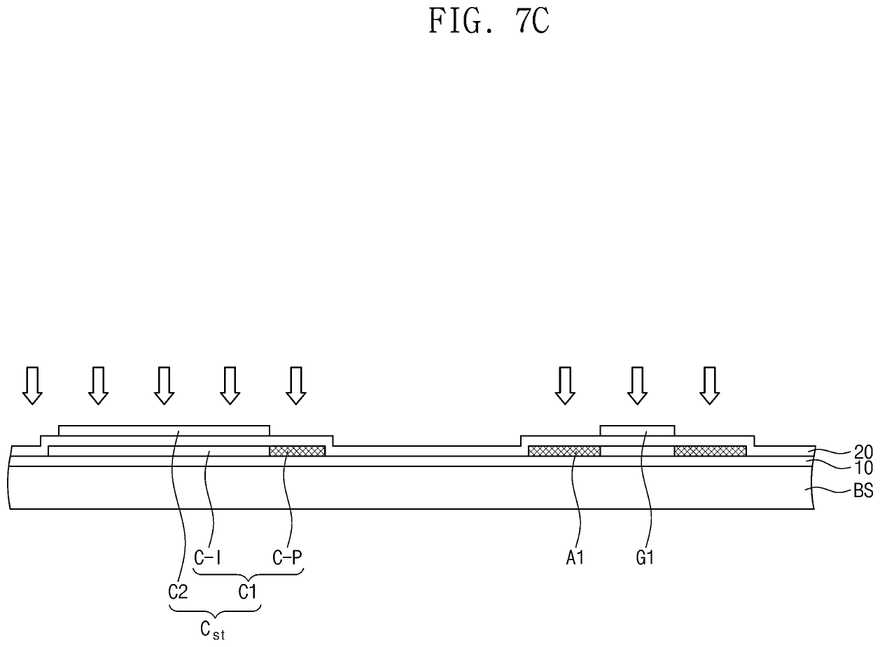

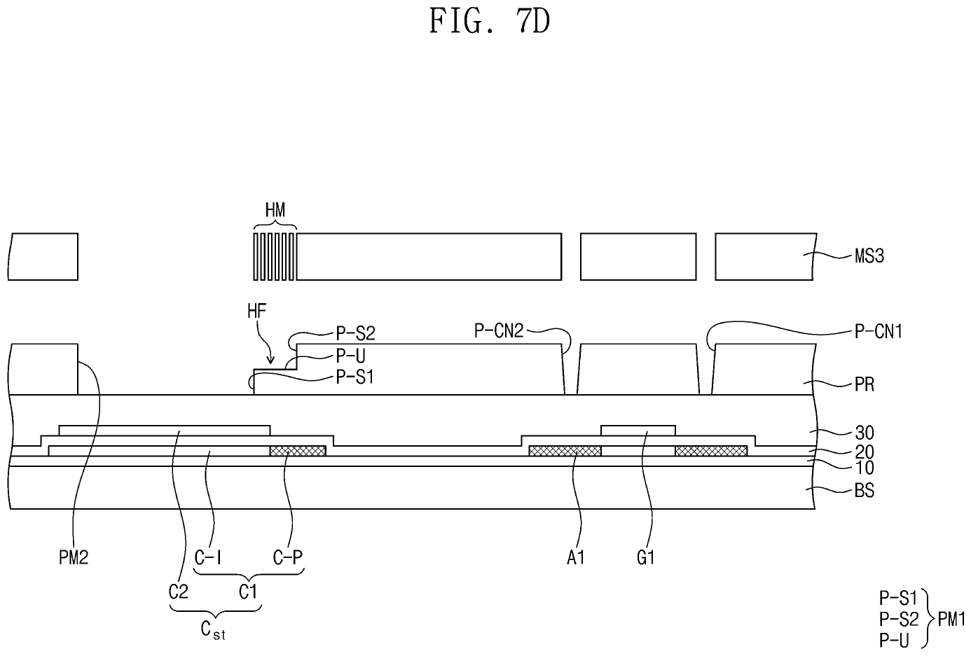

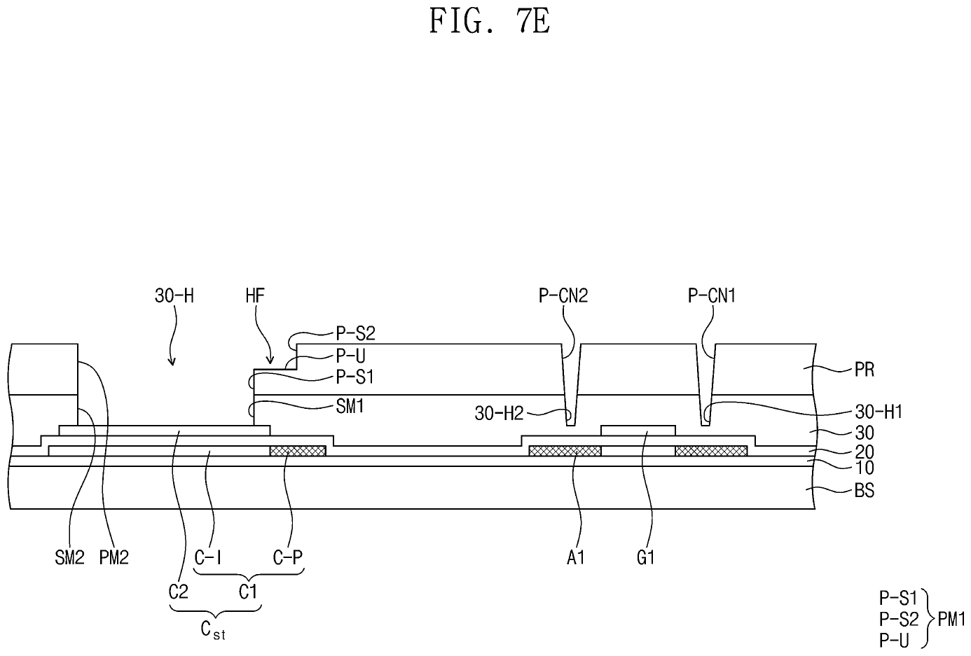

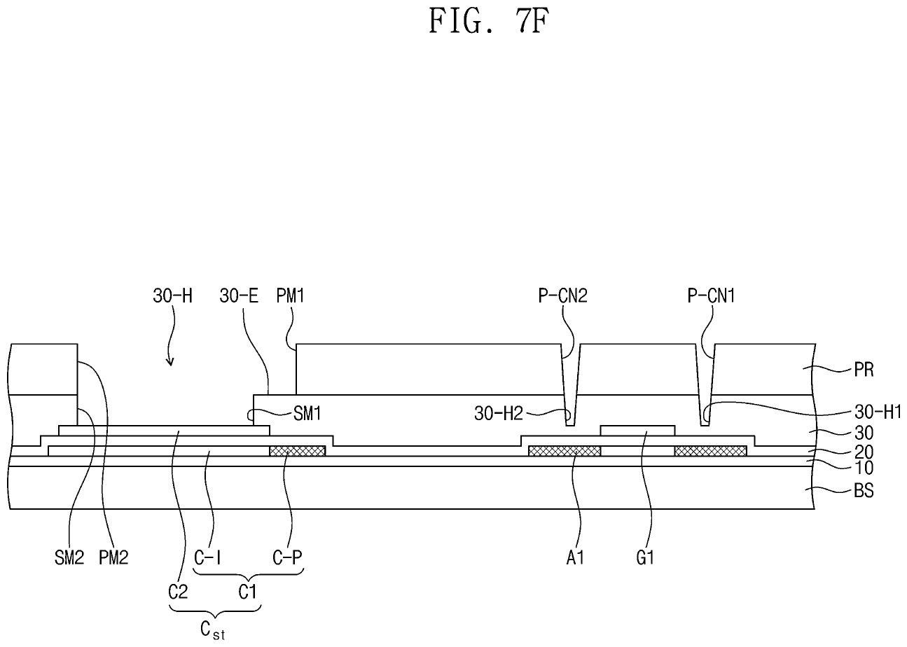

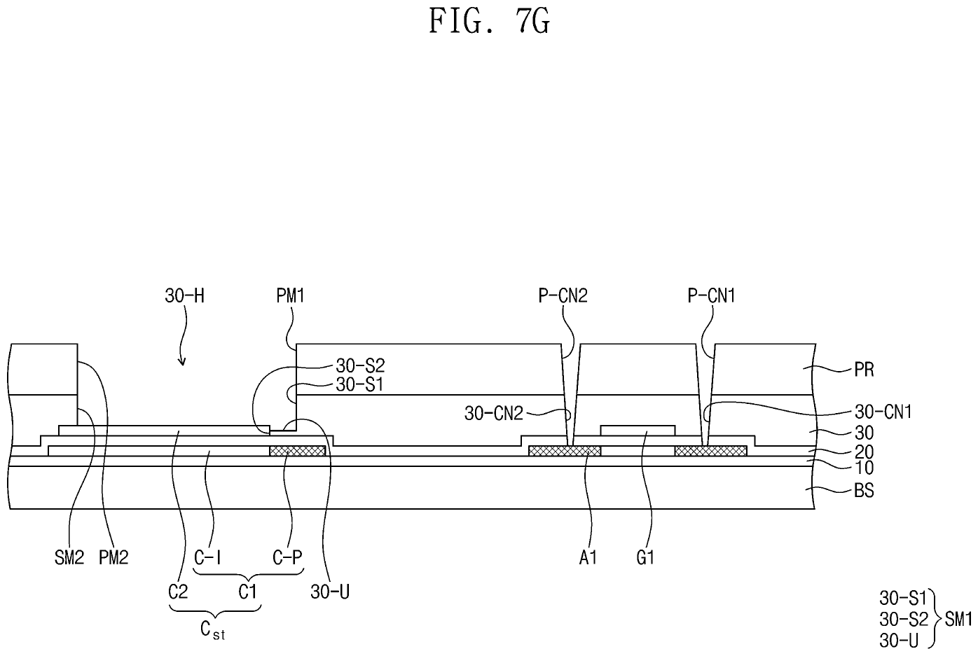

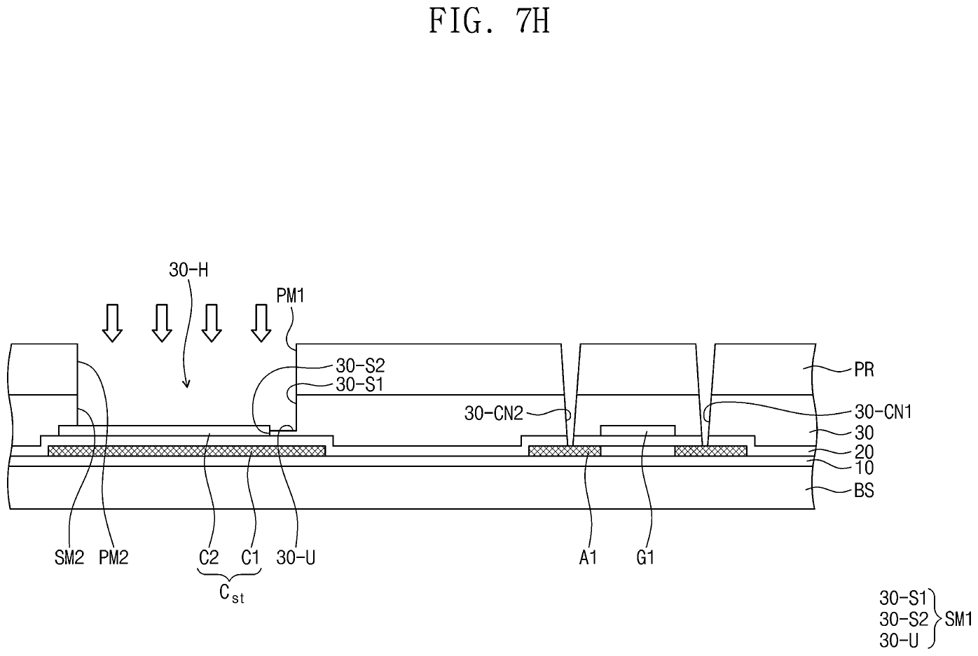

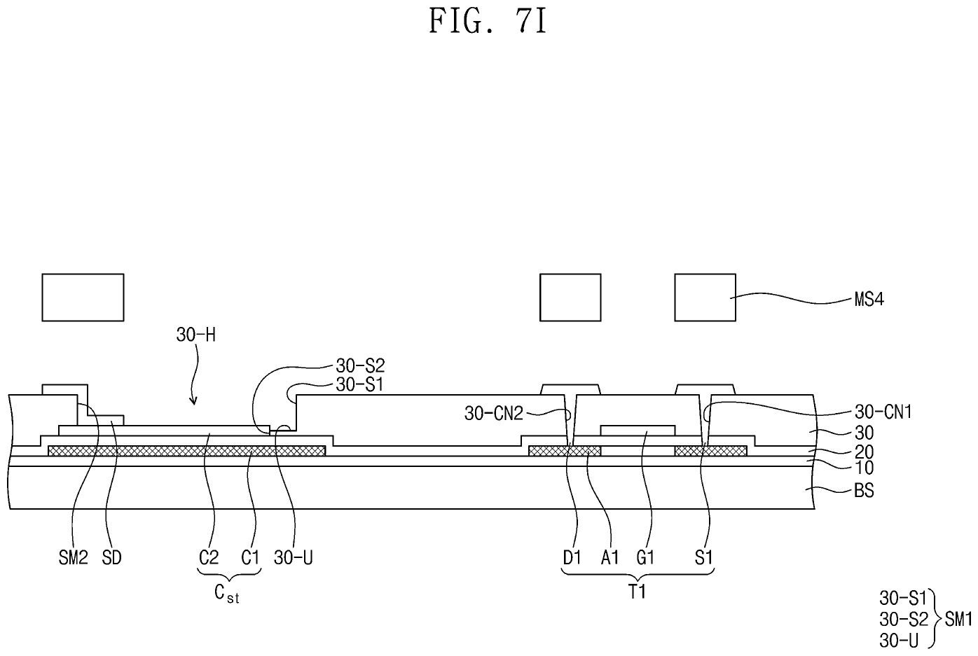

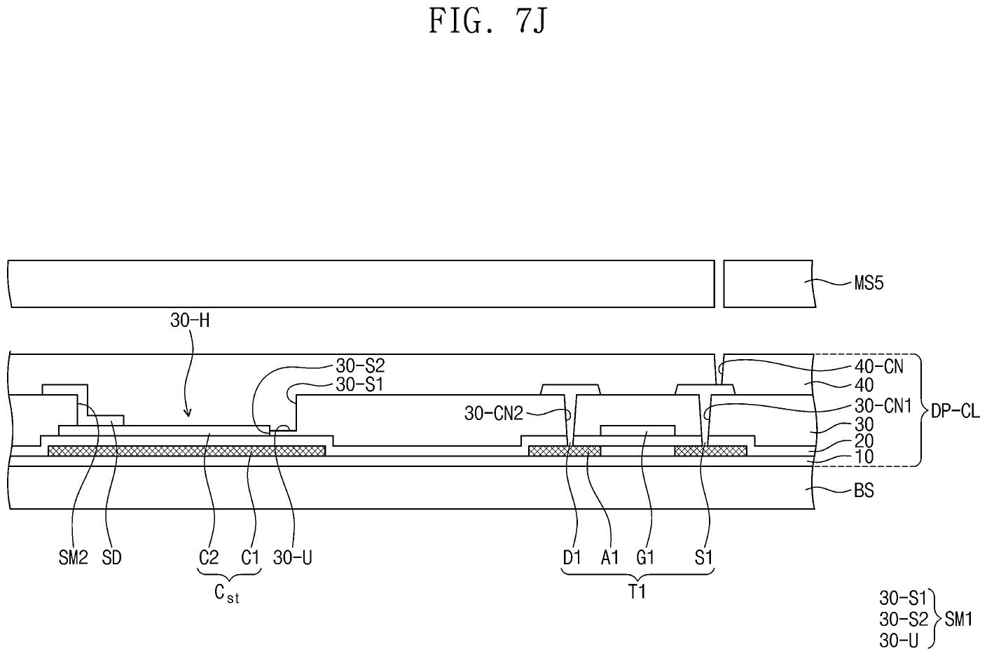

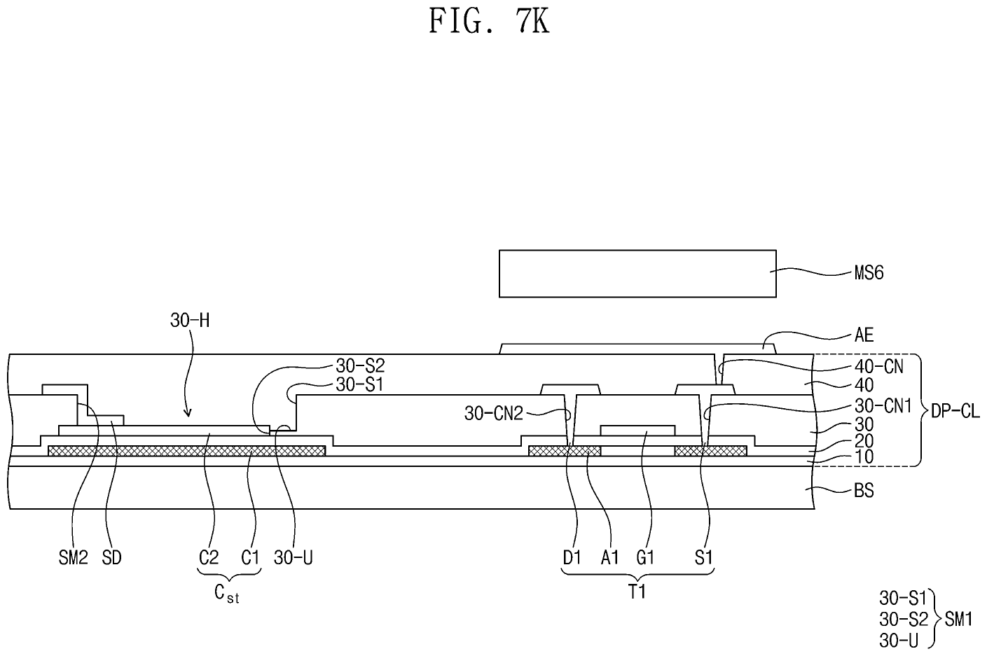

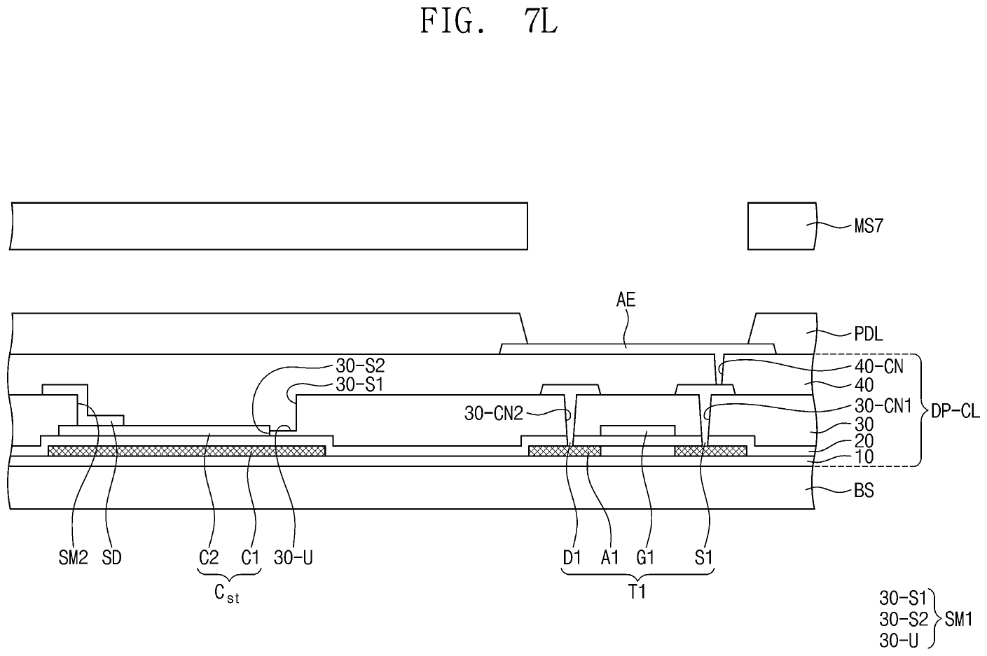

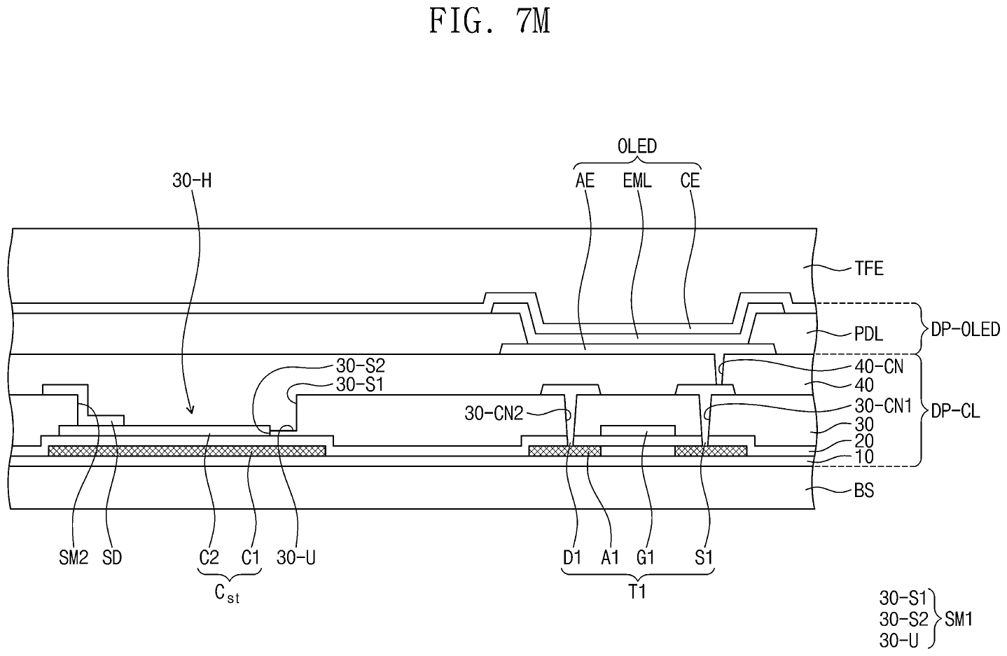

FIGS. 7A to 7M are cross-sectional views illustrating an embodiment of a method for manufacturing a display panel according to the inventive concept. A method for manufacturing the display panel DP described with reference to FIG. 5 will be described with reference to FIGS. 7A to 7M.

Referring to FIG. 7A, the method for manufacturing a display panel in an embodiment may include forming a first insulating layer 10 (or a lower insulating layer) on a base layer BS. The first insulating layer 10 may be formed by applying an inorganic material to an entirety of the surface of the base layer BS.

Then, the method may include forming a first electrode C1 and a semiconductor pattern A1 on the base layer BS. The first electrode C1 and the semiconductor pattern A1 may be formed by applying a polysilicon-containing material to an entirety of the surface of the first insulating layer 10 and patterning the polysilicon-containing material through a first mask MS1.

Then, referring to FIG. 7B, the method for manufacturing a display panel in an embodiment may include forming a second insulating layer 20 (or an inter-insulating layer) on the first insulating layer 10. The second insulating layer 20 may be formed by applying an inorganic material to an entirety of the surface of the first insulating layer 10.

Thereafter, the method may include forming a second electrode C2 and a gate G1 on the second insulating layer 20. The second electrode C2 and the gate G1 may be formed by applying a metal to an entirety of the surface of the second insulating layer 20 and patterning the metal through a second mask MS2. The metal in an embodiment may include molybdenum.

The second electrode C2 may be patterned to overlap the first electrode C1, and the gate G1 may be patterned to overlap the semiconductor pattern A1. In the illustrated embodiment, the second electrode C2 may expose at least a portion of the first electrode C1.

Afterwards, referring to FIG. 7C, the method for manufacturing a display panel in an embodiment may include doping the first electrode C1 and the semiconductor pattern A1. According to a doping process, a first portion C-P, of the first electrode C1, which does not overlap the second electrode C2 may be doped, and a second portion C-I, of the first electrode C1, which overlaps the second electrode C2 may not be doped. A region, of the semiconductor pattern A1, which does not overlap the gate G1 may be doped. Accordingly, a region, of the semiconductor pattern A1, which overlaps the gate G1 may be defined as a channel region. In the illustrated embodiment, a portion of each of the first electrode C1 and the semiconductor pattern A1 may be doped with a P-type dopant.

Then, referring to FIG. 7D, the method for manufacturing a display panel in an embodiment may include forming a third insulating layer 30 (or an intermediate insulating layer) on the second insulating layer 20. The third insulating layer 30 may be formed by applying an organic material to the second insulating layer 20. Thereafter, the method may include forming a photoresist layer PR on the third insulating layer 30. The photoresist layer PR may function as a mask for patterning the third insulating layer 30. The photoresist layer PR may be patterned through a third mask MS3. In an embodiment, a portion of the third mask MS3 may be a half-tone mask HM. A plurality of slits overlapping the first portion C-P of the first electrode C1 and spaced apart from each other may be defined in the half-tone mask HM. A stepped region HF may be defined in a portion, of the photoresist layer PR, which overlaps the half-tone mask HM. The stepped region HF may overlap an end of the second electrode C2.

Photo-contact holes P-CN1 and P-CN2 may be defined in a region overlapping openings of the third mask MS3. Each of the photo-contact holes P-CN1 and P-CN2 may overlap the semiconductor pattern A1.

According to the inventive concept, an opening overlapping at least a portion of the second electrode C2 may be defined in the photoresist layer PR. The opening may be defined by one side surface PM1 which defines the stepped region HF, and another side surface PM2 opposite to the one side surface PM1. The one side surface PM1 may have a first side surface P-S1 which faces the another side PM2, an upper surface P-U which is connected to the first side surface P-S1 and parallel to an upper surface of the third insulating layer 30, and a second side surface P-S2 which is connected to the upper surface P-U and spaced apart from the first side surface P-S1. The stepped region HF may be defined from the first side surface P-S1, the upper surface P-U, and the second side surface P-S2.

Then, referring to FIG. 7E, the method for manufacturing a display panel in an embodiment may include patterning the third insulating layer 30. A groove 30-H which overlaps the opening of the photoresist layer PR, and preliminary contact holes 30-H1 and 30-H2 which overlap the photo-contact holes P-CN1 and P-CN2 may be defined in the third insulating layer 30. The groove 30-H may be defined by penetration of the third insulating layer 30 and expose the second electrode C2. The preliminary contact holes 30-H1 and 30-H2 may be defined by removing a portion of the third insulating layer 30. In an embodiment, the groove 30-H and the preliminary contact holes 30-H1 and 30-H2 may be defined through a dry etching process.

Thereafter, referring to FIG. 7F, the method for manufacturing a display panel in an embodiment may include removing the stepped region HF of the photoresist layer PR. As the stepped region HF of the photoresist layer PR is removed, an upper surface 30-E of the third insulating layer 30 overlapping the first portion C-P of the first electrode C1 may be exposed.

Afterwards, referring to FIG. 7G and FIG. 7H, the method for manufacturing a display panel in an embodiment may include patterning the third insulating layer 30. In this operation, a portion of the third insulating layer 30 overlapping the upper surface 30-E which has been described with reference to FIG. 7F may be removed. As one side surface SM1 which defines the groove 30-H, a first side surface 30-S1, a second side surface 30-S2, and an upper surface 30-U, which define a step, may be formed.

The first side surface 30-S1 may contact one side of the second electrode C2. The upper surface 30-U may extend from the first side surface 30-S1 and may be connected to the second side surface 30-S2. The upper surface 30-U may overlap a portion, of the first electrode C1, which is exposed from the second electrode C2.

According to the inventive concept, as the half-tone mask HM is used as the third mask MS3, the second insulating layer 20 and the third insulating layer 30 may remain on the first portion C-P after the patterning of the third insulating layer 30. Accordingly, the first portion C-P may be protected by the second insulating layer 20 and the third insulating layer 30 in a subsequent process.

In addition, in the patterning of the third insulating layer 30, contact holes 30-CN1 and 30-CN2 which expose the semiconductor pattern A1 may be defined by removing the preliminary contact holes 30-H1 and 30-H2 defined in FIG. 7E.

According to the inventive concept, the method may include doping the second portion C-I of the first electrode C1 during a process same as a process for defining the contact holes 30-CN1 and 30-CN2 which expose the semiconductor pattern A1.

As used herein, “the same process” may be defined as a process performed before use of a fourth mask MS4 (refer to FIG. 7I) which is different from the third mask MS3 used in FIG. 7D.

In a doping process described with reference to FIG. 7C, as the second portion C-I overlaps the second electrode C2, the second portion C-I may not be doped. As described with reference to FIG. 7E, in a process for defining the groove 30-H, a portion of the second electrode C2 and the third insulating layer 30 may be etched by an etchant at the same time, and a thickness of the second electrode C2 may become smaller. Accordingly, a doping material may easily penetrate the second portion C-I. The doping material in an embodiment may be boron. Accordingly, after a doping process, the first electrode C1 may be impregnated with boron.

According to the inventive concept, since the half-tone mask HM is used, disconnection of the first electrode C1 may be prevented, and a process for doping the first electrode C1 and a process for defining the contact holes 30-CN1 and 30-CN2 may be performed in the same process. In addition, the number of masks used in a manufacturing process of a display panel may be reduced. Accordingly, a display panel manufactured through a simplified process with reduced manufacturing costs and a method for manufacturing the same may be provided.

Then, referring to FIG. 7I, the method for manufacturing a display panel in an embodiment may include forming a source S1 and a drain D1. In addition, the method may further include forming a conductive pattern SD. The source S1 and the drain D1 may be formed by forming a conductive material on the third insulating layer 30 and patterning the conductive material through a fourth mask MS4. The source S1 may be disposed in the first contact hole 30-CN1 to contact one portion of the semiconductor pattern A1, and the drain D1 may be disposed in the second contact hole 30-CN2 to contact another portion of the semiconductor pattern A1. The conductive pattern SD and the source S1 and the drain D1 may be formed with the same mask and may include the same material as each other. The conductive pattern SD may be branched off from either of the source S1 or the drain D1 and disposed in the groove 30-H to contact the second electrode C2.

Thereafter, referring to FIG. 7J, the method for manufacturing a display panel in an embodiment may include forming a fourth insulating layer 40 (or an upper insulating layer) on the third insulating layer 30. The fourth insulating layer 40 may be formed by applying an organic material to an entirety of the surface of the third insulating layer 30. Through a fifth mask MS5, a contact hole 40-CN may be defined in the fourth insulating layer 40. The contact hole 40-CN may expose the source S1.

Next, referring to FIG. 7K, the method for manufacturing a display panel in an embodiment may include forming a first electrode AE. The first electrode AE may be formed by applying a conductive material to the fourth insulating layer 40 and patterning the conductive material through a sixth mask MS6. The first electrode AE may be disposed in the contact hole 40-CN to contact the source S1.

Afterwards, referring to FIG. 7L, the method for manufacturing a display panel in an embodiment may include forming a pixel defining film PDL. The pixel defining film PDL may be formed by applying an organic material to the fourth insulating layer 40. Through a seventh mask MS7, an opening may be defined in the pixel defining film PDL. The opening may expose at least a portion of the first electrode AE.

Then, referring to FIG. 7M, the method for manufacturing a display panel in an embodiment may further include forming a thin-film encapsulation layer TFE. The thin-film encapsulation layer TFE may include inorganic layers and an organic layer disposed between the inorganic layers. The inorganic layers may be formed by chemical vapor deposition (“CVD”) method.

In an embodiment of the inventive concept, a manufacturing process of a display panel may be simplified, and manufacturing costs of the display panel May be reduced.

Although the embodiments of the inventive concept have been described, it is understood that the inventive concept should not be limited to these embodiments but various changes and modifications may be made by a person skill in the art within the spirit and scope of the inventive concept as hereinafter claimed.

Therefore, the technical scope of the inventive concept is not limited to the contents described in the detailed description of the specification, but should be defined by the accompanying claims.

What is claimed is:

1. A display panel, comprising:
a base layer;
a transistor disposed on the base layer, and including a semiconductor pattern, a gate overlapping the semiconductor pattern, and a source and a drain connected to the semiconductor pattern;
a light-emitting element connected to the transistor;
a capacitor including a first electrode disposed in a same layer as the semiconductor pattern, and a second electrode disposed on the first electrode;
an inter-insulating layer disposed between the semiconductor pattern and the gate; and
an intermediate insulating layer disposed between the gate and the source and the gate and the drain, the intermediate insulating layer including:
a side surface in which a groove which exposes the second electrode is defined, the side surface including:
a first side surface in contact with the second electrode;
an upper surface overlapping a portion of the first electrode; and
a second side surface spaced apart from the first side surface.

2. The display panel of claim 1, wherein the inter-insulating layer and the intermediate insulating layer are disposed on the portion of the first electrode, and the portion of the first electrode does not overlap the second electrode.

3. The display panel of claim 1, wherein the source and the drain contact the semiconductor pattern through contact holes which penetrate the inter-insulating layer and the intermediate insulating layer.

4. The display panel of claim 1, wherein the gate and the second electrode are disposed on the inter-insulating layer, and
a first thickness of the second electrode is smaller than a second thickness of the gate.

5. The display panel of claim 4, wherein a difference between the second thickness and the first thickness ranges from about 400 angstroms to about 700 angstroms.

6. The display panel of claim 1, further comprising a lower insulating layer which is disposed on the base layer and on which the first electrode and the semiconductor pattern are disposed, and an upper insulating layer which is disposed on the intermediate insulating layer and covers the source and the drain.

7. The display panel of claim 6, wherein the upper insulating layer is disposed in the groove and in contact with the second electrode.

8. The display panel of claim 1, further comprising an upper insulating layer,
wherein the light-emitting element comprises an anode connected to the transistor through a contact hole which penetrates the upper insulating layer, a cathode disposed on the anode, and a light-emitting layer disposed between the anode and the cathode.

9. The display panel of claim 1, wherein the first electrode comprises polysilicon and the second electrode comprises molybdenum.

10. The display panel of claim 9, wherein the polysilicon is impregnated with boron.

11. The display panel of claim 9, wherein the semiconductor pattern comprises polysilicon.

12. The display panel of claim 1, wherein the display panel further comprises a thin-film encapsulation layer which covers the light-emitting element.

13. A method for manufacturing a display panel, the method comprising:
forming a first electrode and a semiconductor pattern on a base layer;
forming an inter-insulating layer which covers the first electrode and the semiconductor pattern;
forming, on the inter-insulating layer, a second electrode overlapping the first electrode, and a gate overlapping the semiconductor pattern;
doping the first electrode which does not overlap the second electrode, and the semiconductor pattern which does not overlap the gate;
forming an intermediate insulating layer which covers the second electrode and the gate, and a photoresist layer on the intermediate insulating layer;
forming a stepped region in the photoresist layer which overlaps an end of the second electrode through a half-tone mask in which a plurality of slits is defined, and patterning the photoresist layer so that the intermediate insulating layer overlapping a portion of the second electrode is exposed;
patterning the intermediate insulating layer so that the portion of the second electrode is exposed;
removing the stepped region of the photoresist layer; and
removing the intermediate insulating layer exposed by the photoresist layer through the removing the stepped region,
wherein the stepped region overlaps a portion, of the first electrode, which does not overlap the second electrode, and
the inter-insulating layer remains on the portion of the first electrode.

14. The method of claim 13, wherein the patterning the photoresist layer comprises removing a portion of a region, of the inter-insulating layer, which is spaced apart from the gate and overlaps the semiconductor pattern, and
removing the inter-insulating layer exposed by the photoresist layer comprises removing the portion of the inter-insulating layer so that the semiconductor pattern is exposed.

15. The method of claim 14, further comprising forming a source and a drain on the inter-insulating layer,
wherein the source and the drain contact the semiconductor pattern exposed by the inter-insulating layer.

16. The method of claim 15, wherein the intermediate insulating layer covers the source and the drain, and
wherein the intermediate insulating layer contacts the portion of the second electrode exposed by the inter-insulating layer.

17. The method of claim 16, further comprising:
defining a contact hole in the intermediate insulating layer so that a portion of the source is exposed; and
forming an anode connected to the source through the contact hole.

18. The method of claim 13, wherein the first electrode and the semiconductor pattern comprise polysilicon.

19. The method of claim 13, further comprising, after the removing the inter-insulating layer exposed by the photoresist layer, doping a portion, of the first electrode, which overlaps the second electrode.

20. The method of claim 13, wherein after patterning the inter-insulating layer, a thickness of the second electrode becomes smaller than a thickness of the gate.
